(19) United States
(12) Patent Application Publication
(10) Pub. No.: US 2026/0173453 A1
(43) Pub. Date: Jun. 18, 2026

(54) SEMICONDUCTOR DEVICES

(71) Applicant: Samsung Electronics Co., Ltd., Suwon-si (KR)

(72) Inventors: Sanghyeok Yu, Suwon-si (KR); Sunjung Lee, Suwon-si (KR); Seungjin Jeong, Suwon-si (KR); Sungnam Lyu, Suwon-si (KR); Dosun Lee, Suwon-si (KR)

(21) Appl. No.: 19/352,982

(22) Filed: Oct. 8, 2025

(30) Foreign Application Priority Data
Dec. 18, 2024 (KR) 10-2024-0189369

(51) Int. Cl. H10D 30/67; H10B 12/00; H10D 1/68

(52) U.S. Cl. CPC H10D 30/6738; H10B 12/315; H10B 12/482; H10D 1/716; H10D 30/6731; H10D 30/6757; H10B 12/05

(57) ABSTRACT

A semiconductor device may include a bit line extending in a first direction, a channel on the bit line, the channel extending in a vertical direction perpendicular to an upper surface of the bit line, and the channel including an oxide semiconductor material, a gate insulating pattern and a gate electrode sequentially stacked in the first direction from the channel and a contact structure. The contact structure may include a first contact pattern on the channel, the first contact pattern including a reducing material a second contact pattern on the first contact pattern, the second contact pattern including a material with a Schottky Barrier Height (SBH) with respect to the channel that is equal to or less than about 0.2 eV and a third contact pattern on the second contact pattern, the third contact pattern including an electrically conductive material.

### CROSS-REFERENCE TO RELATED APPLICATION

This application claims priority under 35 U.S.C. § 119 to Korean Patent Application No. 10-2024-0189369 filed on Dec. 18, 2024 in the Korean Intellectual Property Office, the disclosure of which is hereby incorporated by reference in its entirety.

### TECHNICAL FIELD

Example implementations of the present disclosure relate to a semiconductor device. More particularly, the present disclosure relates to a memory device including a vertical channel transistor.

### BACKGROUND

In order to improve an integration degree of a semiconductor device, a memory device including a vertical channel transistor has been developed, and recently an oxide semiconductor material is used as a channel of the vertical channel transistor.

### SUMMARY

Example implementations provide a semiconductor device having improved characteristics. For example, example implementations of the semiconductor device can reduce a contact resistance between a channel including an oxide semiconductor material and a metallic contact plug configured to transfer an electrical signal to the channel.

According to example implementations of the present disclosure, there is a provided a semiconductor device. The semiconductor device may include a bit line extending in a first direction, a channel on the bit line, the channel extending in a vertical direction perpendicular to an upper surface of the bit line, and the channel including an oxide semiconductor material, a gate insulating pattern and a gate electrode sequentially stacked in the first direction from the channel and a contact structure. The contact structure may include a first contact pattern on the channel, the first contact pattern including a reducing material a second contact pattern on the first contact pattern, the second contact pattern including a material with a Schottky Barrier Height (SBH) with respect to the channel that is equal to or less than about 0.2 eV, and a third contact pattern on the second contact pattern, the third contact pattern including an electrically conductive material.

According to example implementations of the present disclosure, there is a provided a semiconductor device. A semiconductor device may include a bit line extending in a first direction, a channel on the bit line, the channel extending in a vertical direction perpendicular to an upper surface of the bit line, and the channel including an oxide semiconductor material, a gate insulating pattern and a gate electrode sequentially stacked in the first direction from the channel, and a contact structure. The contact structure may include a first contact pattern on the channel, the first contact pattern including a first metal, a second contact pattern on the first contact pattern, the second contact pattern including a second metal, a barrier pattern on the second contact pattern, the barrier pattern including a third metal, and a third contact pattern on the barrier pattern, the third contact pattern including a fourth metal. The third contact pattern may include an upper portion having a first width and a lower portion that is disposed under the upper portion and has a second width smaller than the first width.

According to example implementations of the present disclosure, there is a provided a semiconductor device. A semiconductor device may include bit lines on a substrate, each of the bit lines extending in a first direction parallel to an upper surface of the substrate, and the bit lines being spaced apart from each other in a second direction that is parallel to the upper surface of the substrate and intersects with the first direction, gate electrodes on the bit lines, each of the gate electrodes extending in the second direction, and the gate electrodes being spaced apart from each other in the first direction, a gate insulating pattern on a sidewall in the first direction of each of the gate electrodes, a channel contacting an upper surface of each of the bit lines and a sidewall in the first direction of the gate insulating pattern, the channel including an oxide semiconductor material, a contact structure, and a capacitor on the contact structure. The contact structure may include a first contact pattern including a reducing material, a second contact pattern on the first contact pattern, the second contact pattern including a material with a Schottky Barrier Height (SBH) with respect to the channel that is equal to or less than about 0.2 eV, and a third contact pattern on the second contact pattern, the third contact pattern including an electrically conductive material.

In the semiconductor device in accordance with example implementations, the first contact pattern including the reducing material may be disposed on the channel including the oxide semiconductor material, and the first contact pattern may absorb oxygen from the channel so that an oxygen vacancy in the channel may be increased. Thus, a carrier concentration of the channel may be increased and an inner resistance may be decreased.

The second contact pattern including a low Schottky Barrier Height (SBH) material with respect to the channel may be disposed on the first contact pattern, and thus a contact resistance between the barrier pattern on the second contact pattern and the channel may decrease.

As a result, a transistor including the channel may have an increased On-Current, and the semiconductor device including the transistor may have improved electrical characteristics.

### BRIEF DESCRIPTION OF THE DRAWINGS

FIGS. 1 to 3 are a plan view and cross-sectional views illustrating a semiconductor device in accordance with example implementations.

FIGS. 4 to 29 are plan views and cross-sectional views illustrating a method of manufacturing a semiconductor device in accordance with example implementations.

FIGS. 30 and 31 are a plan view and a cross-sectional view, respectively, illustrating a semiconductor device in accordance with example implementations.

FIGS. 32 and 33 are a plan view and a cross-sectional view, respectively, illustrating a method of manufacturing a semiconductor device in accordance with example implementations.

### DETAILED DESCRIPTION

The above and other aspects and features of a semiconductor device and a method of manufacturing the same in accordance with example implementations will become readily understood from detailed descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure, and process from another material, layer (film), region, electrode, pad, pattern, structure, and process. Thus, a first material, layer (film), region, electrode, pad, pattern, structure, and process discussed below could be termed a second or third material, layer (film), region, electrode, pad, pattern, structure, and process without departing from the teachings of the present disclosure.

Hereinafter, in the specification (and not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In example implementations, the first and second directions D1 and D2 may be orthogonal to each other. Each of the first to third directions D1, D2, and D3 may include not only a direction shown in the drawings but also a direction that is opposite thereto.

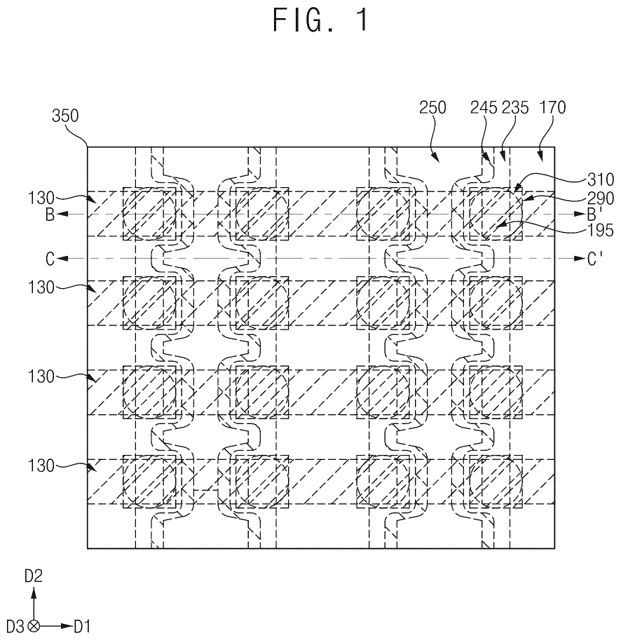

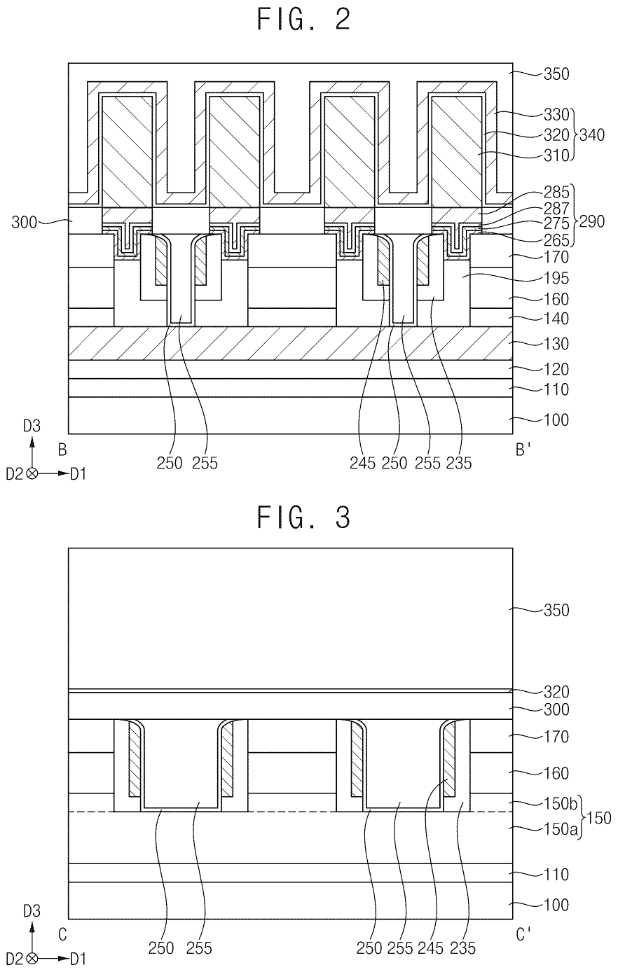

FIGS. 1 to 3 are a plan view and cross-sectional views illustrating a semiconductor device in accordance with example implementations. Particularly, FIG. 1 is the plan view, FIG. 2 is a cross-sectional view taken along a line B-B′ of FIG. 1, and FIG. 3 is a cross-sectional view taken along a line C-C′ of FIG. 1.

Referring to FIGS. 1 to 3, the semiconductor device may include a bit line structure, a gate electrode 245, a gate insulating pattern 235, a channel 195, a contact structure 290, and a capacitor 340 on a substrate 100.

The semiconductor device may also include a first insulating layer 110, second to fourth insulating patterns 120, 140, and 250, and first to fifth insulating interlayer patterns 150, 160, 170, 255, and 300.

The substrate 100 may include silicon, germanium, silicon-germanium, or a III-V group compound semiconductor, e.g., GaP, GaAs, GaSb, etc. In example implementations, the substrate 100 may be a silicon-on-insulator (SOI) substrate or a germanium-on-insulator (GOI) substrate.

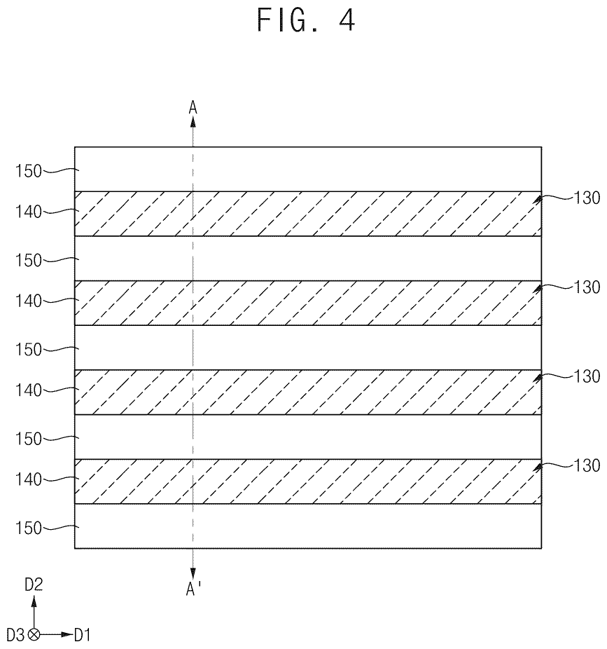

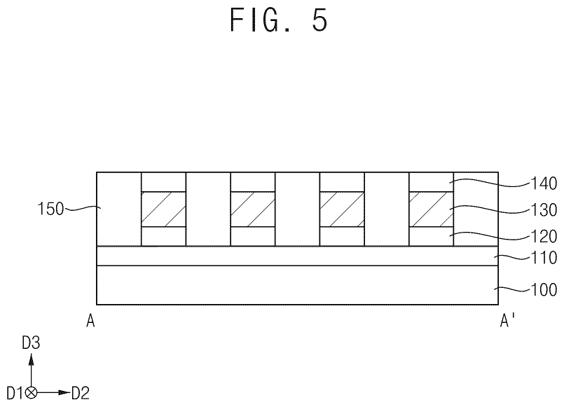

Referring to FIGS. 1 to 3 together with FIGS. 4 and 5, the first insulating layer 110 may be disposed on the substrate 100, and the bit line structure may extend in the first direction D1 on the first insulating layer 110.

In example implementations, the bit line structure may include the second insulating pattern 120, a bit line 130, and the third insulating pattern 140 sequentially stacked in the third direction D3 on the first insulating layer 110. Each of the second insulating pattern 120 and the bit line 130 may extend in the first direction D1, and a plurality of third insulating patterns 140 may be spaced apart from each other in the first direction D1 on the bit line 130.

A plurality of bit line structures may be spaced apart from each other in the second direction D2, and the first insulating interlayer pattern 150 may extend in the first direction D1 on the first insulating layer 110 and may be disposed between neighboring bit line structures in the second direction D2.

The first insulating interlayer pattern 150 may include a lower portion 150a which may be disposed between neighboring bit lines 130 in the second direction D2 and may overlap the bit line 130 in the second direction D2, and an upper portion 150b which may be disposed on and contact the lower portion 150a and may overlap the third insulating pattern 140 in the second direction D2. That is, the upper portion 150b of the first insulating interlayer pattern 150 may be disposed at substantially the same level as the third insulating pattern 140, and thus an upper surface of the upper portion 150b of the first insulating interlayer pattern 150 may be disposed at substantially the same height as an upper surface of the third insulating pattern 140. An upper surface of the lower portion 150a of the first insulating interlayer pattern 150 may be disposed at substantially the same height as an upper surface of the bit line 130.

As the plurality of third insulating patterns 140 are spaced apart from each other in the first direction D1, a plurality of upper portions 150b of the first insulating pattern 150 may also be spaced apart from each other in the first direction D1. Thus, a height of the upper surface of the first insulating interlayer pattern 150 may periodically change in the first direction D1.

Each of the first insulating layer 110 and the first insulating interlayer pattern 150 may include an oxide, e.g., silicon oxide, the bit line 130 may include an electrically conductive material, e.g., a metal, a metal nitride, a metal silicide, etc., and each of the second and third insulating patterns 120 and 140 may include an insulating nitride, e.g., silicon nitride.

The second and third insulating interlayer patterns 160 and 170, each of which may extend in the second direction D2, may be sequentially stacked in the third direction D3 upwardly on the third insulating pattern 140 and the upper portion 150b of the first insulating interlayer 150. Hereinafter, the third insulating pattern 140, the upper portion 150b of the first insulating interlayer pattern 150, and the second and third insulating interlayer patterns 160 and 170 may be collectively referred to as an insulating structure. In example implementations, the insulating structure may extend in the second direction D2, and a plurality of insulating structures may be spaced apart from each other in the first direction D1.

The second insulating interlayer pattern 160 may include an oxide, e.g., silicon oxide, and the third insulating interlayer pattern 170 may include an insulating nitride, e.g., silicon nitride.

The fourth insulating interlayer pattern 255 extending in the second direction D2 and the fourth insulating pattern 250 covering sidewalls in the first direction D1 and a lower surface of the fourth insulating interlayer pattern 255 may be disposed between neighboring insulating structures in the first direction D1. The gate electrode 245, the gate insulating pattern 235 and the channel 195 may be sequentially stacked in the first direction D1 from a sidewall of the fourth insulating pattern 250 between the insulating structure and the fourth insulating pattern 250. Hereinafter, the fourth insulating interlayer pattern 255 and the fourth insulating pattern 250 may be collectively referred to as a division structure. In example implementations, the division structure may extend in the second direction D2, and a plurality of division structures may be spaced apart from each other in the first direction D1. The division structure and the insulating structure may be alternately and repeatedly disposed in the first direction D1.

The channel 195 may contact an upper surface of the bit line 130, and may contact opposite sidewalls of the insulating structure and the division structure neighboring in the first direction D1.

In example implementations, a plurality of channels 195 may be spaced apart from each other in the first direction D1 by the insulating structure and the division structure on each of the bit lines 130.

In example implementations, the channel 195 may include a horizontal portion and a vertical portion. A lower surface of the horizontal portion of the channel 195 may contact the upper surface of the bit line 130, an inner sidewall in the first direction D1 of the horizontal portion of the channel 195 may contact a sidewall of the division structure, and an outer sidewall in the first direction D1 of the horizontal portion of the channel 195 may contact a sidewall of the insulating structure. The vertical portion of the channel 195 may be disposed on and contact the horizontal portion of the channel 195. An inner sidewall in the first direction D1 of the vertical portion of the channel 195 may contact the gate insulating pattern 235, and an outer sidewall in the first direction D1 of the vertical portion of the channel 195 may contact the sidewall of the insulating structure. Thus, in example implementations, a vertical cross-section in the first direction D1 of the channel 195 may have an “L” shape.

In example implementations, an uppermost surface of the channel 195, that is, an upper surface of the vertical portion of the channel 195 may be lower than an upper surface of the insulating structure, that is, an upper surface of the insulating interlayer pattern 170.

In example implementations, the channel 195 may include an oxide semiconductor material, which refers to a material exhibiting semiconductor properties and including a metal oxide component. Specifically, the channel 195 may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓOyN_{z}), magnesium zincoxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indiumzinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ) and indium gallium silicon oxide (InGaSiO).

Similarly to the channel 195, the gate insulating pattern 235 may include a horizontal portion contacting the upper surface of the horizontal portion of the channel 195, and a vertical portion contacting the inner sidewall of the vertical portion of the channel 195. Thus, a vertical cross-section of the gate insulating pattern 235 may have an “L” shape.

Specifically, an inner sidewall in the first direction D1 of the horizontal portion of the gate insulating pattern 235 may contact the division structure, and an outer sidewall in the first direction D1 of the horizontal portion of the gate insulating pattern 235 may contact the inner sidewall of the horizontal portion of the gate insulating pattern 235 and the sidewall of the insulating structure. An outer sidewall in the first direction D1 of the vertical portion of the gate insulating pattern 235 may contact a sidewall of the contact structure 290, the inner sidewall of the vertical portion of the channel 195, and the sidewall of the division structure.

The gate insulating pattern 235 may include a first portion which may contact the inner sidewall of the vertical portion of the channel 195 and the sidewall of the contact structure 290, and a second portion which may contact the sidewall of the insulating structure.

In example implementations, the gate insulating pattern 235 may extend in the second direction D2. However, in a plan view, the gate insulating pattern 235 may extend in a curved shape, instead of a straight-line shape, in the second direction D2. The first portion and the second portion of the gate insulating pattern 235 may not be aligned in the second direction D2 due to the channel 195, and as the first and second portions of the gate insulating pattern 235 are alternatively and repeatedly disposed in the second direction D2, the gate insulating pattern 235 may extend in the curved shape in the second direction D2.

In example implementations, lower surfaces of the first and second portions of the gate insulating pattern 235 may be disposed at different heights from each other. That is, the first portion of the gate insulating pattern 235 may contact the upper surface of the horizontal portion of the channel 195 on the upper surface of the bit line 130, and thus a lower surface of the first portion of the gate insulating pattern 235 may be disposed at the same height as the upper surface of the horizontal portion of the channel 195. However, the second portion of the gate insulating pattern 235 may contact an upper surface of the lower portion 150a of the first insulating interlayer pattern 150 which may be disposed at the same height as the upper surface of the bit line 130, and thus a lower surface of the second portion of the gate insulating pattern 235 may be disposed at the same height as the upper surface of the lower portion 150a of the first insulating interlayer pattern 150.

Thus, the lower surface of the first portion of the gate insulating pattern 235 may be higher than the lower surface of the second portion of the gate insulating pattern 235, and a height of the lower surface of the gate insulating pattern 235 may periodically change in the second direction D2.

In example implementations, an uppermost surface of the gate insulating pattern 235 may be higher than an uppermost surface of the channel 195. The gate insulating pattern 235 may include an oxide, e.g., silicon oxide.

The gate electrode 245 may be disposed on the gate insulating pattern 235. An inner sidewall in the first direction D1 of the gate electrode 245 may contact the division structure, an outer sidewall in the first direction D1 of the gate electrode 245 may contact the inner sidewall of the vertical portion of the gate insulating pattern 235, and a lower surface of the gate insulating 245 may contact an upper surface of the horizontal portion of the gate electrode pattern 235.

In example implementations, similarly to the gate insulating pattern 235, the gate electrode 245 may include a first portion on the first portion of the gate insulating pattern 235, and a second portion on the second portion of the gate insulating pattern 235. In a plan view, the gate electrode 245 may extend in a curved shape, instead of a straight-line shape, in the second direction D2. The first portion and the second portion of the gate electrode 245 may not be aligned in the second direction D2 due to the gate insulating pattern 235, and as the first and second portions of the gate electrode 245 are alternatively and repeatedly disposed in the second direction D2, the gate insulating pattern 235 may extend in the curved shape in the second direction D2.

In example implementations, an uppermost surface of the gate electrode 245 may be lower than that of the gate insulating pattern 235, and may be higher than that of the channel 195. The gate electrode 245 may include an electrically conductive material, e.g., a metal, a metal nitride, or a metal silicide.

Similarly to the gate insulating pattern 235 and the gate electrode 245, the division structure may include a first portion which may contact the inner sidewall of the horizontal portion of the channel 195, the inner sidewall of the first portion of the gate insulating pattern 235 and an inner sidewall of the first portion of the gate electrode 245, and a second portion which may contact an inner sidewall of the second portion of the gate insulating pattern 235 and an inner sidewall of the second portion of the gate electrode 245. In example implementations, a width in the first direction D1 of the first portion of the division structure may be smaller than a width in the first direction D1 of the second portion of the division structure, and thus the width in the first direction D1 of the division structure may periodically change in the second direction D2.

The fourth insulating pattern 250 may contact the upper surface of the bit line 130, an upper surface of the lower portion 150a of the first insulating interlayer 150, the inner sidewall of the horizontal portion of the channel 195, the inner sidewall and the upper surface of the horizontal portion of the gate insulating pattern 235, the inner sidewall and an upper surface of the gate electrode 245. A vertical cross-section in the first direction D1 of the fourth insulating pattern 250 may have an “L” shape.

The fourth insulating interlayer 255 may have an oxide, e.g., silicon oxide, and the fourth insulating pattern 250 may include an insulating nitride, e.g., silicon nitride.

In example implementations, the contact structure 290 may include a lower portion which may contact an upper surface of the channel 195, an outer sidewall of the gate insulating pattern 235 and the sidewall of the insulating structure, and an upper portion which may be disposed on the lower portion and contact an upper surface of the gate insulating pattern 235 and an upper surface of the insulating structure. The upper portion of the contact structure 290 may have a width greater than that of the lower portion of the contact structure 290. However, the contact structure 290 may not contact the upper surface of the gate electrode 245, and may be spaced apart from the gate electrode 245 by the gate insulating pattern 235.

The contact structure 290 may include first and second contact patterns 265 and 275, a barrier pattern 287, and a third contact pattern 285 sequentially stacked in the third direction D3. Each of the first contact pattern 265, the second contact pattern 275, the barrier pattern 287, and the third contact pattern 285 is conformally disposed. For example, each pattern provides conformal coverage of an underlying surface. The third contact pattern 285 may include an upper portion and a lower portion that may be disposed under and contact the upper portion and have a width smaller than that of the upper portion. The barrier pattern 287 may cover a lower surface of the upper portion of the third contact pattern 285 and a sidewall and a lower surface of the lower portion of the third contact pattern 285. The second contact pattern 275 may cover a lower surface of the barrier pattern 287. The first contact pattern 265 may cover a lower surface of the second contact pattern 275.

The first contact pattern 265 may include a reducing material, e.g., titanium. In some implementations, the reducing material is a material with a high bonding energy with oxygen, which may be e.g., equal to or greater than about 7.6 eV.

The second contact pattern 275 may include a material with a low Schottky Barrier Height (SBH) with respect to the channel 195, e.g., molybdenum, and the SBH may be, e.g., equal to or less than about 0.2 eV with respect to the channel 195. The barrier pattern 287 may include a metal nitride, e.g., titanium nitride (TiN), titanium silicon nitride (TiSiN), etc., and the third contact pattern 285 may include a low resistance metal, e.g., tungsten.

In example implementations, a plurality of contact structures 290 may be spaced apart from each other in each of the first and second directions D1 and D2, and the contact structure 290 may be arranged in a lattice pattern or a honeycomb pattern in a plan view.

The fifth insulating interlayer pattern 300 may be disposed on the third and fourth insulating interlayer patterns 170 and 255, the fourth insulating pattern 250, and the gate insulating pattern 235, and may cover an upper sidewall of the contact structure 290. The fourth insulating interlayer pattern 255 may include an insulating material, e.g., silicon oxide, silicon nitride, etc.

The capacitor 340 may include first and second capacitor electrodes 310 and 330, and dielectric layer 320 between the first and second capacitor electrodes 310 and 330. The first capacitor electrode 310 may be disposed on the contact structure 290, the dielectric layer 320 may be disposed on an upper surface and a sidewall of the first capacitor electrode 310 and an upper surface of the fifth insulating interlayer pattern 300, and the second capacitor electrode 330 may be disposed on the dielectric layer 320.

As the plurality of contact structures 290 are spaced apart from each other in each of the first and second directions D1 and D2, a plurality of first capacitor electrodes 310 may be spaced apart from each other in each of the first and second directions D1 and D2.

In example implementations, the first capacitor electrode 310 may have a shape of, e.g., a circle, an ellipse, a polygon, a polygon with rounded corners, etc., in a plan view. The first capacitor electrode 310 may be arranged in a lattice pattern or a honeycomb pattern in a plan view.

Each of the first and second capacitor electrodes 310 and 330 may include a metal, e.g., titanium, tantalum, etc., a metal nitride, e.g., titanium nitride, tantalum nitride, etc., or a metal silicide, etc., and the dielectric layer 320 may include, e.g., a metal oxide.

A plate electrode 350 may be disposed on the second capacitor electrode 330, and may include, e.g., doped silicon-germanium, or undoped silicon-germanium.

In the semiconductor device, a current may flow in the channel 195 disposed between the bit line 130 and the contact structure 290 in the third direction D3, that is, in the vertical direction, and thus the semiconductor device may include a vertical channel transistor (VCT) which may have a vertical channel.

As illustrated above, the semiconductor device may include the channel 195 which may include an oxide semiconductor material, and the contact structure 290 which may include the first contact pattern 265, the second contact pattern 275, the barrier pattern 287 and the third contact pattern 285 sequentially stacked on the channel 195.

The first contact pattern may include a reducing material, may contact the upper surface of the channel 195, and may capture oxygen included in the channel 195. Thus, an oxygen vacancy of the channel 195 may increase and a carrier concentration of the channel 195 may increase, so that an inner resistance of the channel 195 may decrease. The second contact pattern 275 may include a material with a low SBH with respect to the channel 195, so that contact resistances between the channel 195 and the barrier pattern 287 on the second contact pattern 275 and between the channel 195 and the third contact pattern 285 on the second contact pattern 275 may decrease.

When compared to a contact structure including only the barrier pattern 287 and the third contact pattern 285, the contact structure 290 may further include the first contact pattern 265 and the second contact pattern 275, and thus an inner resistance of the channel 195 may decrease, contact resistances between the channel 195 and the barrier pattern 287, and between the channel 195 and the third contact pattern 285 may decrease, so that a transistor including the channel 195 may have an increased On-Current, and that the semiconductor device including the transistor may have improved electrical characteristics.

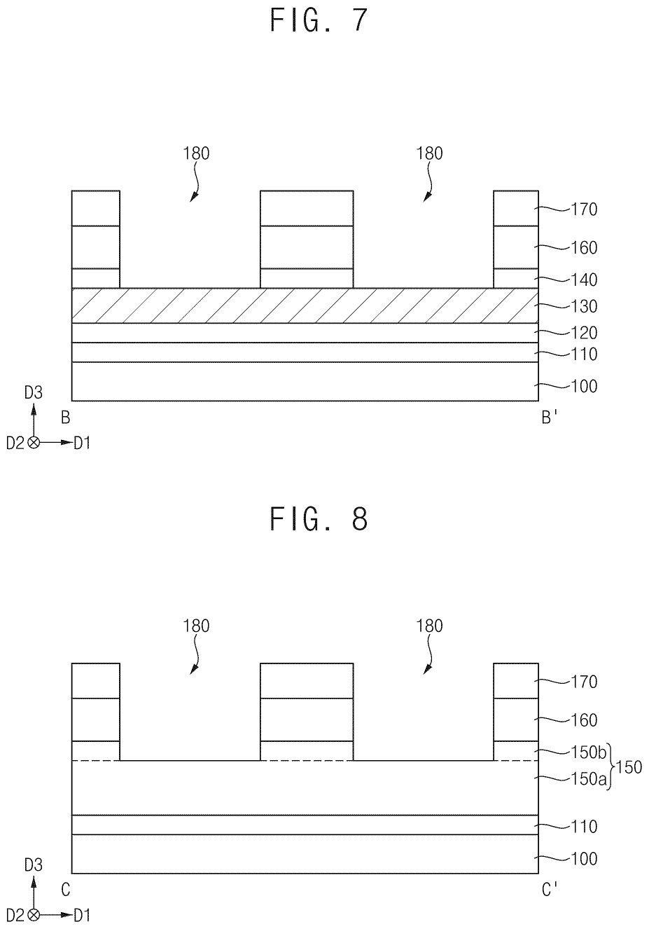

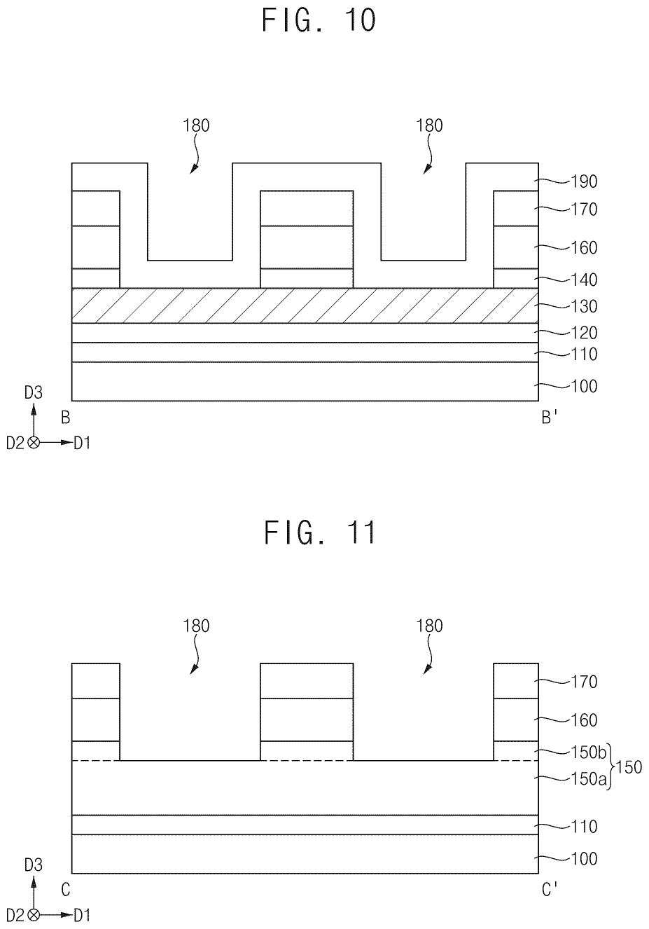

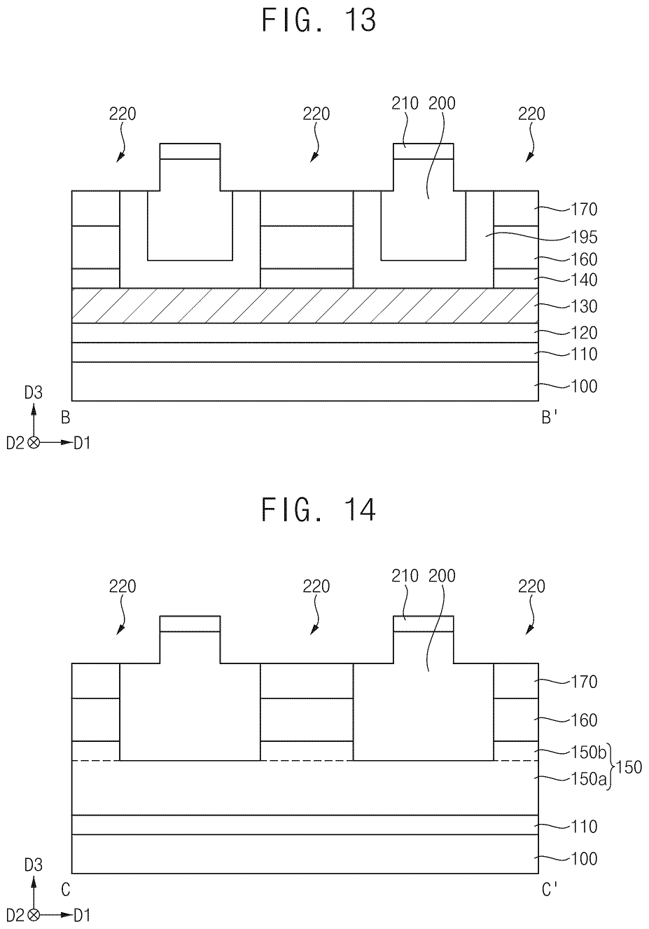

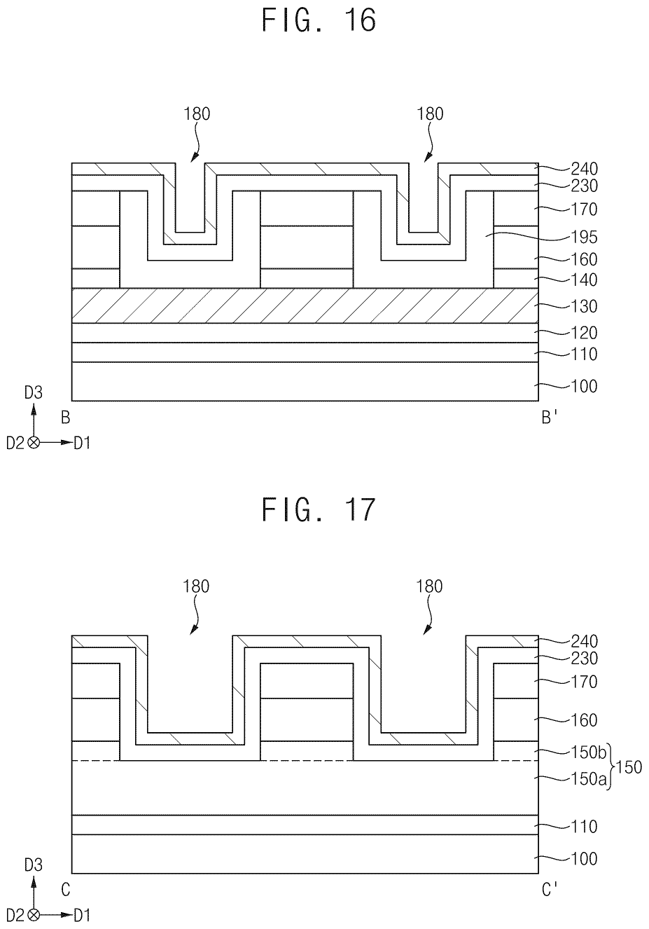

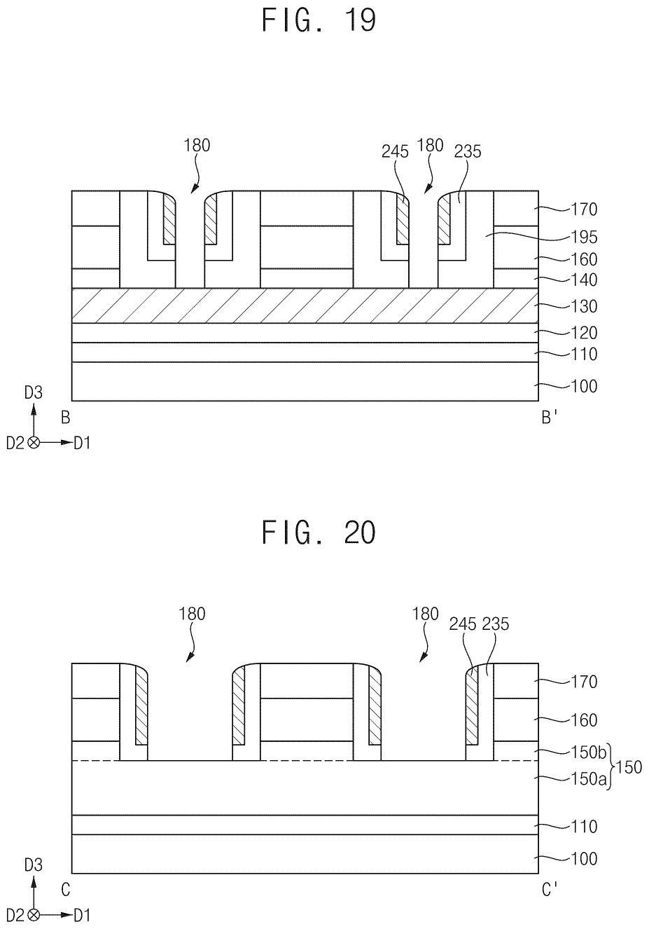

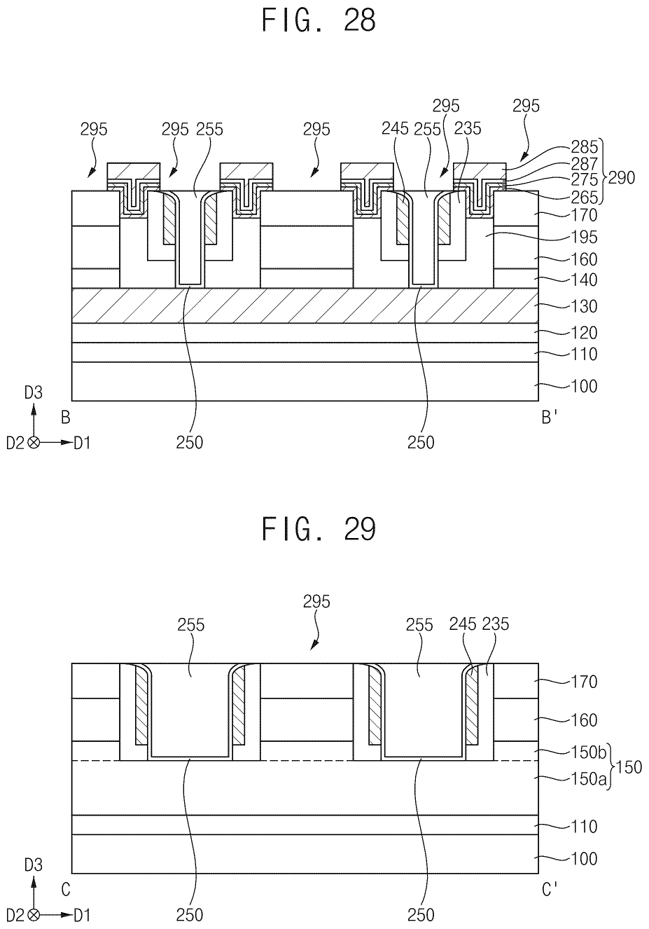

FIGS. 4 to 29 are plan views and cross-sectional views illustrating a method of manufacturing a semiconductor device in accordance with example implementations. Specifically, FIGS. 4, 6, 9, 12, 15, 18 and 27 are the plan views, FIG. 5 is a cross-sectional view taken along a line A-A′ of FIG. 4, FIGS. 7, 10, 13, 16, 19, 21, 23, 24, 25, 26 and 28 are cross-sectional views taken along lines B-B′ of corresponding plan views, respectively, and FIGS. 8, 11, 14, 17, 20, 22, and 29 are cross-sectional views taken along lines C-C′ of corresponding plan views, respectively.

Referring to FIGS. 4 and 5, a first insulating layer 110, a second insulating layer, a bit line layer and a third insulating layer may be sequentially stacked on a substrate 100, and the third insulating layer, the bit line layer and the second insulating layer may be patterned to form a third insulating pattern 140, a bit line 130 and a second insulating pattern 120, respectively.

The second insulating pattern 120, the bit line 130, and the third insulating pattern 140 may be collectively referred to as a bit line structure. In example implementations, the bit line structure may extend in the first direction D1 on the substrate 100, and a plurality of bit line structures may be spaced apart from each other in the second direction D2. Thus, a first opening may be formed between neighboring bit line structures in the second direction D2 to expose an upper surface of the first insulating layer 110.

A first insulating interlayer may be formed on the bit line structures and the first insulating layer 110 to fill the first opening, and a planarization process may be performed on an upper portion of the first insulating interlayer until upper surfaces of the bit line structures are exposed, and thus a first insulating interlayer pattern 150 may be formed between neighboring bit line structures to extend in the first direction D1.

In example implementations, the planarization process may include, e.g., a chemical mechanical polishing (CMP) process and/or an etch back process.

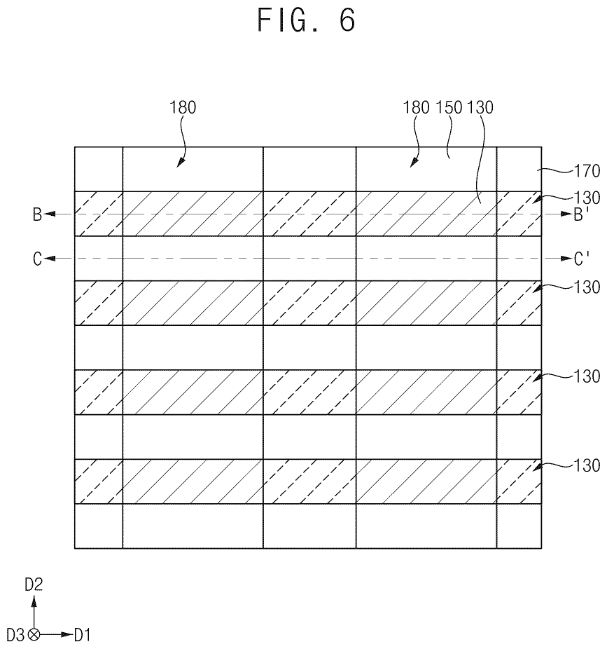

Referring to FIGS. 6 and 8, a second insulating interlayer and a third insulating interlayer may be sequentially formed on the bit line structures and the first insulating interlayer patterns 150, and the third insulating interlayer and the second insulating interlayer may be partially removed by, e.g., a dry etching process, so that a second opening 180 may be formed to extend in the second direction D2 and to expose upper surfaces of the third insulating pattern 140 and the first insulating interlayer pattern 150.

Thus, the third insulating interlayer may be divided into a plurality of third insulating interlayer patterns 170, each of which may extend in the second direction D2, spaced apart from each other in the first direction D1, and the second insulating interlayer may be divided into a plurality of second insulating interlayer patterns 160, each of which may extend in the second direction D2, spaced apart from each other in the first direction D1.

A portion of the third insulating pattern 140 exposed by the second opening 180 may be removed to enlarge the second opening 180 downwardly in the third direction D3, and thus the third insulating pattern 140 extending in the first direction D1 may be divided into a plurality of portions spaced apart from each other in the first direction D1, and an upper portion of the first insulating interlayer pattern 150 exposed by the second opening 180 may also be removed.

Thus, the first insulating interlayer pattern 150 may include a lower portion 150a that may be disposed on the first insulating layer 110 at the same level as the second insulating pattern 120 and the bit line 130, and an upper portion 150b that may be disposed on the lower portion 150a adjacent to the third insulating pattern 140 in the second direction D2. As the third insulating pattern 140 is divided into the plurality of portions spaced apart from each other in the first direction D1, the upper portion 150b of the first insulating interlayer pattern 150 may also be divided into a plurality of portions spaced apart from each other in the first direction D1.

Hereinafter, the third insulating pattern 140, the upper portion 150b of the first insulating interlayer pattern 150, and the second insulating interlayer pattern 160 and the third insulating interlayer pattern 170 sequentially stacked in the third direction D3 on the third insulating pattern 140 and the upper portion 150b of the first insulating interlayer pattern 150 may be collectively referred to as a bar structure. In example implementations, the bar structure may extend in the second direction D2, and a plurality of bar structures may be spaced apart from each other in the first direction D1.

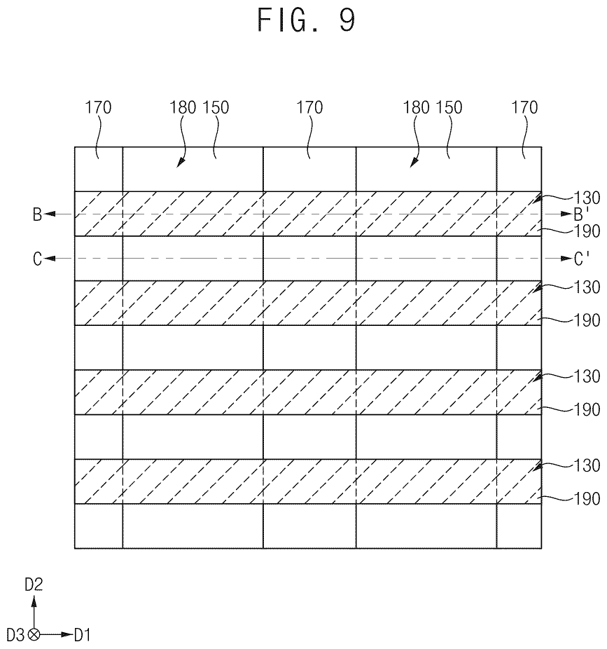

Referring to FIGS. 9 to 11, a channel layer 190 may be formed on upper surfaces of the bit line 130 and the lower portion 150a of the first insulating interlayer pattern 150 exposed by the second opening 180, and a sidewall and an upper surface of the bar structure, and the channel layer 190 may be partially removed be an etching process.

Thus, the channel layer 190 may extend in the first direction D1 on the bit line 130, and a plurality of channel layers 190 may be spaced apart from each other in the second direction D2.

In example implementations, the channel layer 190 may be formed at a relatively low temperature by performing a deposition process such as an atomic layer deposition (ALD) process, a chemical vapor deposition (CVD) process, etc., and may include an amorphous oxide semiconductor material.

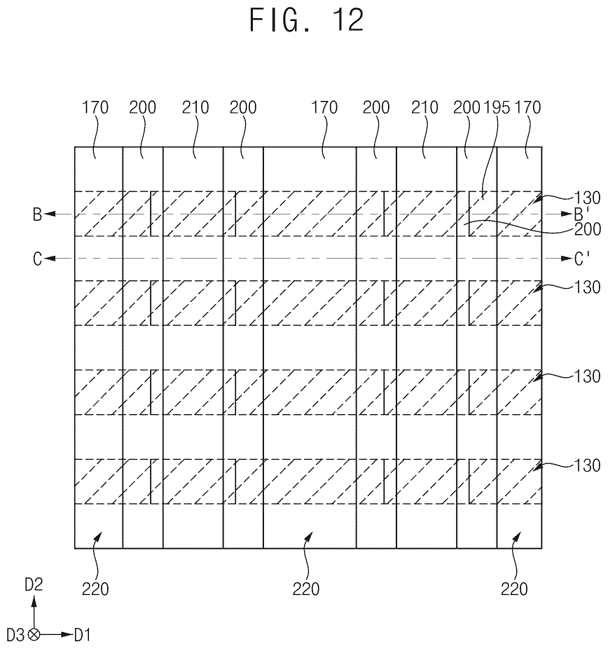

Referring to FIGS. 12 to 14, a sacrificial layer 200 may be formed on the channel layer 190, the lower portion 150a of the first insulating interlayer pattern 150 and the bar structure, a mask 210 may be formed on the sacrificial layer 200, and an etching process may be performed using the mask 210 as an etching mask to partially etch the sacrificial layer 200 and the channel layer 190, so that a third opening 220 may be formed to expose an upper surface of the third insulating interlayer pattern 170 and an uppermost surface of the channel layer 190.

The mask 210 may include, e.g., a photoresist pattern, and the sacrificial layer 200 may include, e.g., spin-on-hardmask (SOH), amorphous carbon layer (ACL), etc.

As the etching process is performed, the channel layer 190 may be transformed into a channel 195.

In example implementations, the mask 210 may extend in the second direction D2, and a plurality of masks 210 may be spaced apart from each other in the first direction D1, so that the third opening 220 may extend in the second direction D2, and that a plurality of third openings 220 may be spaced apart from each other in the first direction D1. A portion of the channel layer 190 on the third insulating interlayer pattern 170 may be removed to form the channel 195, and thus a plurality of channels 195 may be spaced apart from each other in each of the first and second directions D1 and D2.

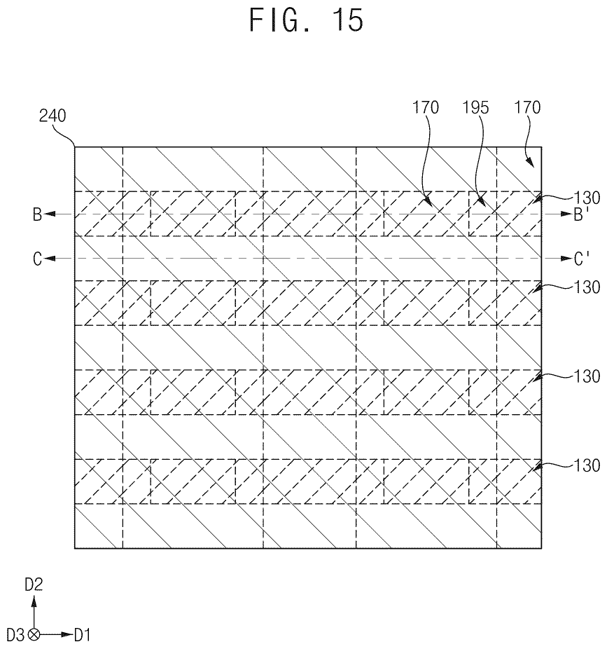

Referring to FIGS. 15 to 17, the mask 210 and the sacrificial layer 200 may be removed by an ashing process and/or a stripping process, and thus an upper surface of the channel 196 may be exposed.

A gate insulating layer 230 and a gate electrode layer 240 may be sequentially formed on the upper surface of the channel 195, the upper surface and the sidewall of the bar structure, and the lower portion 150a of the first insulating interlayer pattern 150. The gate insulating layer 230 and the gate electrode layer 240 may not entirely fill the second opening 180.

In example implementations, the gate insulating layer 230 and the gate electrode layer 240 may be formed at a relatively high temperature by performing a deposition process such as an atomic layer deposition (ALD) process, a chemical vapor deposition (CVD) process, etc.

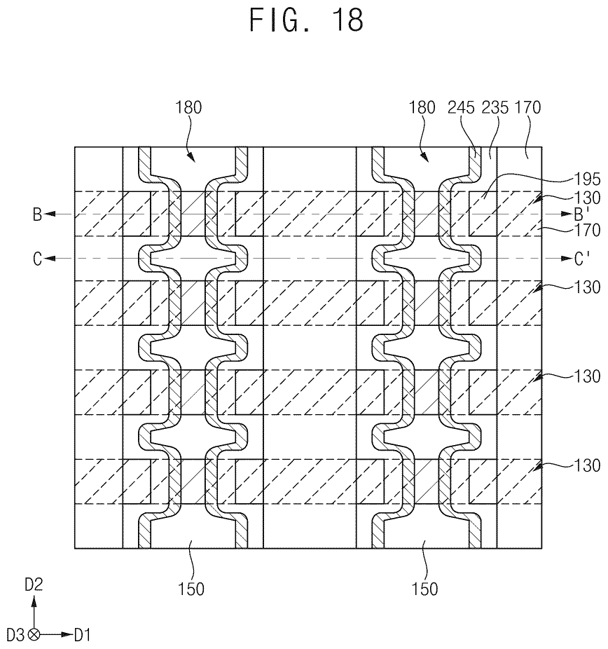

Referring to FIGS. 18 to 20, an etching process may be performed on the gate electrode layer 240, the gate insulating layer 230 and the channel 195, and thus the gate electrode layer and the gate insulating layer 230 may be transformed into a gate electrode 245 and a gate insulating pattern 235, respectively, and the channel 195 may be divided into a plurality of portions of the channel 195 spaced apart from each other in the first direction D1. The second opening 180 may be enlarged downwardly in the third direction D3 to partially expose an upper surface of the bit line 130 and an upper surface of the lower portion 150a of the first insulating interlayer pattern 150.

In example implementations, the gate insulating pattern 235 and the gate electrode 245 may be sequentially stacked on an inner sidewall in the first direction D1 of the channel 195 on the bit line 130, and may be sequentially stacked on the sidewall of the bar structure on the first insulating interlayer pattern 150.

Hereinafter, a portion of the gate insulating pattern 235 contacting an inner sidewall in the first direction D1 of the channel 195 may be referred to as a first portion of the gate insulating pattern 235, and a portion of the gate insulating pattern 235 contacting the sidewall of the bar structure may be referred to as a second portion of the gate insulating pattern 235. A portion of the gate electrode 245 on the first portion of the gate insulating pattern 235 may be referred to as a first portion of the gate electrode 245, and a portion of the gate electrode 245 on the second portion of the gate insulating pattern 235 may be referred to as a second portion of the gate electrode 245.

In example implementations, the gate insulating pattern 235 may extend in the second direction D2. However, in a plan view, the gate insulating pattern 235 may extend in a curved shape in the first direction D1, instead of a straight-line shape in the second direction D2. The first portion and the second portion of the gate insulating pattern 235 may not be aligned in the second direction D2 due to the channel 195, and as the first and second portions of the gate insulating pattern 235 are alternatively and repeatedly disposed in the second direction D2, the gate insulating pattern 235 may extend in the curved shape in the second direction D2.

In example implementations, lower surfaces of the first and second portions of the gate insulating pattern 235 may be formed at different heights from each other. That is, the first portion of the gate insulating pattern 235 may contact an upper surface of a portion of the channel 195 on the upper surface of the bit line 130, and thus a lower surface of the first portion of the gate insulating pattern 235 may be formed at the same height as the upper surface of the portion of the channel 195. However, the second portion of the gate insulating pattern 235 may contact an upper surface of the lower portion 150a of the first insulating interlayer pattern 150 which may be formed at the same height as the upper surface of the bit line 130, and thus a lower surface of the second portion of the gate insulating pattern 235 may be formed at the same height as the upper surface of the lower portion 150a of the first insulating interlayer pattern 150. Thus, the lower surface of the first portion of the gate insulating pattern 235 may be higher than the lower surface of the second portion of the gate insulating pattern 235, and a height of the lower surface of the gate insulating pattern 235 may periodically change in the second direction D2.

Similarly, the gate electrode 245 may also extend in the second direction D2, however, in a plan view, the gate electrode 245 may extend in a curved shape in the first direction D1, instead of a straight-line shape, in the second direction D2. A height of a lower surface of the gate electrode 245 may periodically change in the second direction D2.

In example implementations, a vertical cross-section in the first direction D1 of each of the first and second portions of each of the channel 195 and the gate insulating pattern 235 may have an “L” shape.

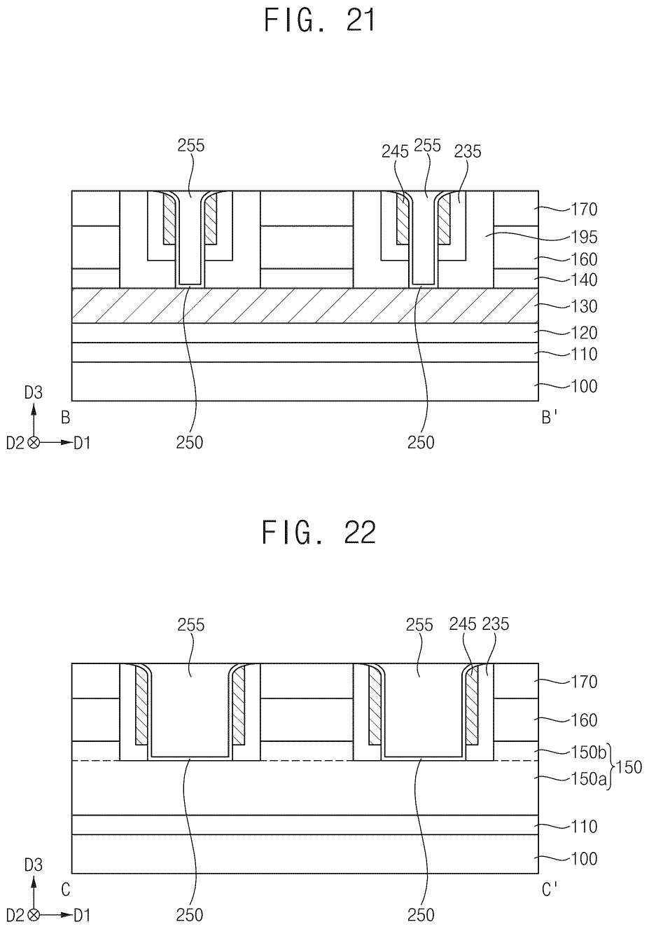

Referring to FIGS. 21 and 22, a fourth insulating layer may be formed on the third insulating interlayer pattern 170, the channel 195, the bit line 130, the first insulating interlayer pattern 150, the gate insulating pattern 235 and the gate electrode 245, a fourth insulating interlayer may be formed on the fourth insulating layer to fill the second opening 180, and a planarization process may be performed on upper portions of the fourth insulating interlayer and the fourth insulating layer until the upper surface of the third insulating interlayer pattern 170 is exposed.

In example implementations, the planarization process may include a chemical mechanical polishing (CMP) process and/or an etch back process. As the planarization process is performed, the fourth insulating interlayer and the fourth insulating layer may remain as a fourth insulating interlayer pattern 255 and a fourth insulating pattern 250, respectively, in the second opening, and each of the fourth insulating pattern 250 and the fourth insulating interlayer pattern 255 may extend in the second direction D2 on the channel 195 and the first insulating interlayer pattern 150.

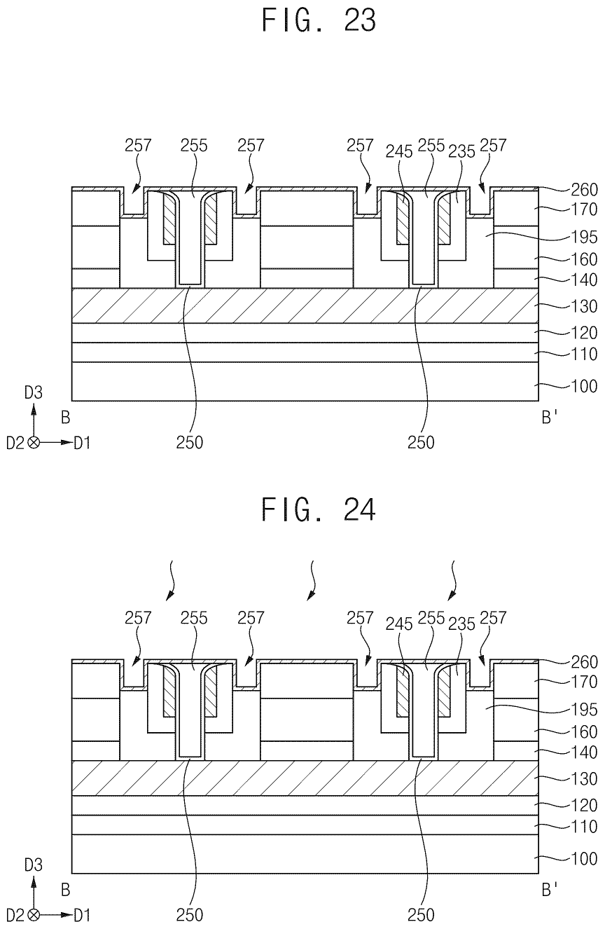

Referring to FIG. 23, an upper portion of the channel 195 may be removed by, e.g., a wet etching process.

Thus, an uppermost surface of the channel 195 may be lower than upper surfaces of the gate insulating pattern 235, the gate electrode 245, the fourth insulating pattern 250, and the fourth insulating interlayer pattern 255, and a recess 257 may be formed to expose an uppermost surface of the channel 195.

In example implementations, a plurality of recesses 257 may be spaced apart from each other in each of the first and second directions D1 and D2.

A first contact layer 260 may be formed on the third insulating interlayer pattern 170, the channel 195, the gate insulating pattern 235, the gate electrode 245, the fourth insulating pattern 250, and the fourth insulating interlayer pattern 255.

The first contact layer 260 may include a reducing material, e.g., titanium. In some implementations, the reducing material is a material with a high bonding energy to oxygen, and thus may have a high oxygen scavenging characteristic. Thus, the first contact layer 260 may absorb oxygen from the channel 195 under the first contact layer 260 to increase an oxygen vacancy of the channel 195, and an oxygen concentration of the first contact layer 260 may increase to form an oxide in the first contact layer 260.

Referring to FIG. 24, a cleaning process may be performed using, e.g., argon (Ar) to remove the oxide in the first contact layer 260.

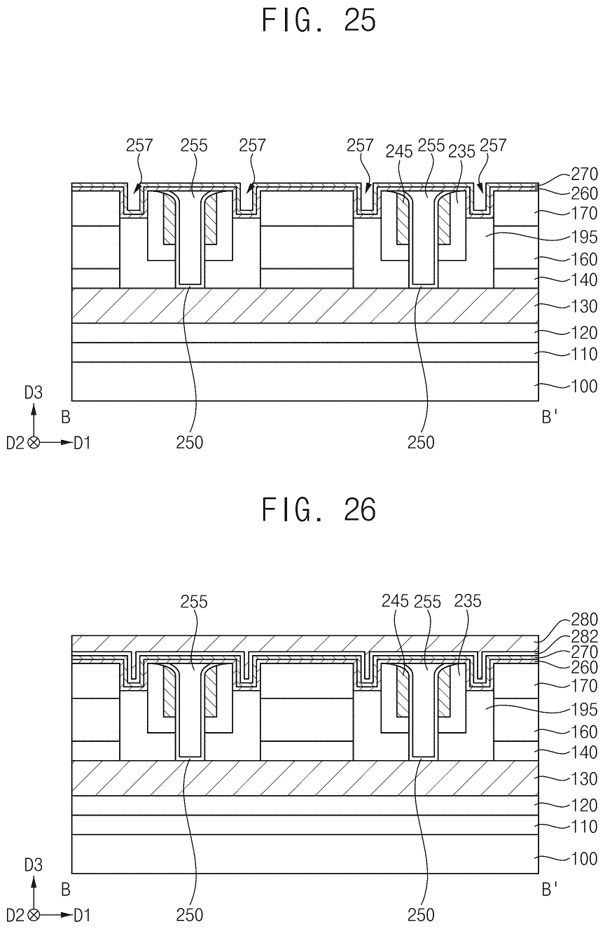

Referring to FIG. 25, a second contact layer 270 may be formed on the first contact layer 260.

The second contact layer 270 may include a low Schottky Barrier Height (SBH) material with respect to the channel 195, e.g., molybdenum.

Referring to FIG. 26, a barrier layer 282 may be formed on the second contact layer 270, and a third contact layer 280 may be formed on the barrier layer 282 to fill the recess 257.

The barrier layer 282 may include a metal nitride, e.g., titanium nitride (TiN), titanium silicon nitride (TiSiN), and the third contact layer 280 may include a low resistance metal, e.g., tungsten.

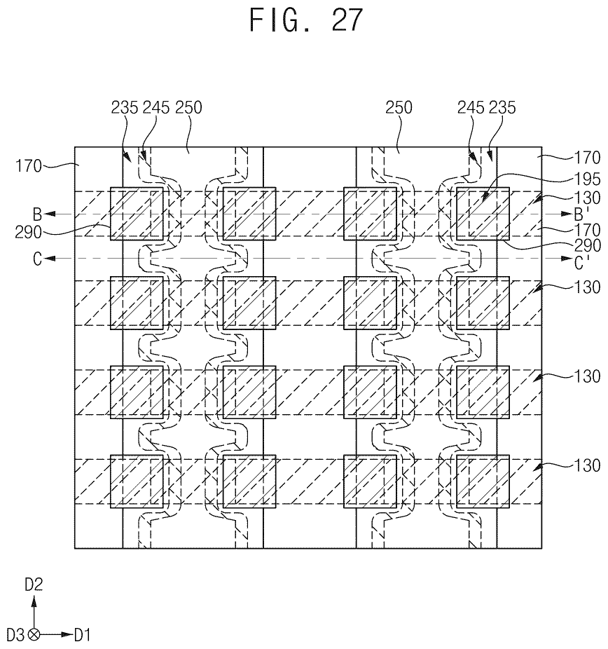

Referring to FIGS. 27 to 29, the first to third contact layers 260, 270 and 280, and the barrier layer 282 may be partially removed by an etching process to be transformed into first to third contact patterns 265, 275 and 285, and a barrier pattern 287, respectively, and the first to third contact patterns 265, 275 and 285, and the barrier pattern 287 may collectively form a contact structure 290.

A plurality of contact structures 290 may be spaced apart from each other in each of the first and second directions D1 and D2, and a fourth opening 295 may be formed between neighboring contact structures 290 to expose upper surfaces of the third and fourth insulating interlayer patterns 170 and 255, and the fourth insulating pattern 250.

In example implementations, the contact structures 290 may be arranged in a lattice pattern or a honeycomb pattern in a plan view.

In example implementations, the contact structure 290 may include a lower portion that may be disposed in the recess 257 and have a first width substantially the same as that of the channel 195, and an upper portion that may be disposed on the lower portion and have a second width greater than that of the lower portion. Thus, the contact structure 290 may have a planar area greater than that of the channel 195.

Referred to FIGS. 1 to 3 again, a fifth insulating interlayer may be formed on the contact structure 290, the third and fourth insulating interlayer patterns 170 and 255, and the fourth insulating pattern 250 to fill the fourth opening 295, and, e.g., a planarization process may be performed on the fifth insulating interlayer until an upper surface of the contact structure 290 is exposed to form a fifth insulating interlayer pattern 300.

A first capacitor electrode 310 may be formed to contact the upper surface of the contact structure 290, a dielectric layer 320 may be formed on an upper surface and a sidewall of the first capacitor electrode 310 and an upper surface of the fifth insulating interlayer pattern 300, and a second capacitor electrode 330 may be formed on an upper surface of the dielectric layer 320.

The first capacitor electrode 310, the dielectric layer 320, and the second capacitor electrode 330 may collectively form a capacitor 340. In example implementations, a plurality of first capacitor electrodes 310 may be spaced apart from each other in each of the first and second directions D1 and D2, and may contact upper surfaces of corresponding contact structures 290, respectively.

A plate electrode 350 may be further formed on the capacitor 340. The plate electrode 350 may include, e.g., doped silicon-germanium or undoped silicon-germanium.

The fabrication of the semiconductor device may be completed by the above processes.

As illustrated above, the first contact layer 260, the second contact layer 270, the barrier layer 282 and the third contact layer 280 may be formed on the channel 195 including an oxide semiconductor material, and the first contact layer 260, the second contact layer 270, the barrier layer 282 and the third contact layer 280 may be etched to be transformed into the first contact pattern 265, the second contact pattern 275, the barrier pattern 287 and the third contact pattern 285, respectively, which may form the contact structure 290.

The first contact layer 260 contacting the channel 195 may include a material with a high bonding energy to oxygen and may capture oxygen included in the channel 195. Thus, an oxygen vacancy of the channel 195 may increase and a carrier concentration of the channel 195 may increase, so that an inner resistance of the channel 195 may be improved. The second contact pattern 275 may include a material with a low Schottky Barrier Height (SBH) with respect to the channel 195, so that contact resistances between the channel 195 and the barrier pattern 287 on the second contact pattern 275 and between the channel 195 and the third contact pattern 285 on the second contact pattern 275 may be improved.

When compared to a contact structure including, e.g., only the barrier pattern 287 and the third contact pattern 285, in the contact structure 290 in accordance with example implementations, which may further include the first contact pattern 265 and the second contact pattern 275 in addition to the barrier pattern 287 and third contact pattern 285, an inner resistance of the channel 195 may be improved, and contact resistances between the channel 195 and the barrier pattern 287, and between the channel 195 and the third contact pattern 285 may be improved, so that a transistor including the channel 195 may have an increased On-Current, and that the semiconductor device including the transistor may have improved electrical characteristics.

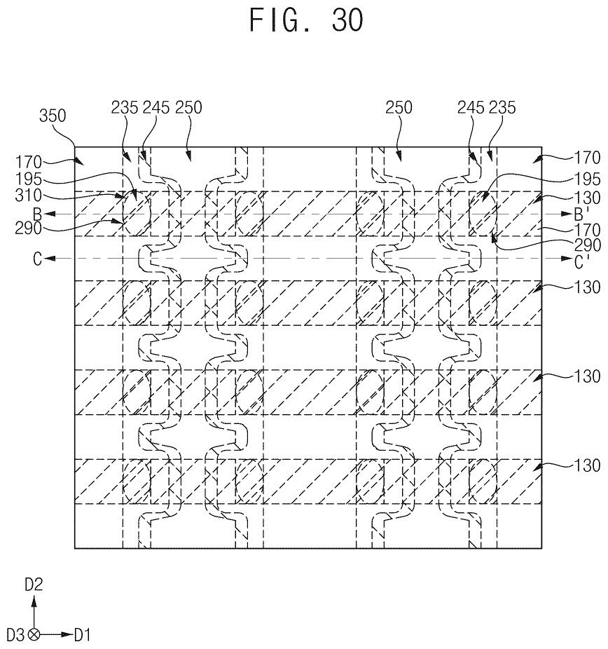

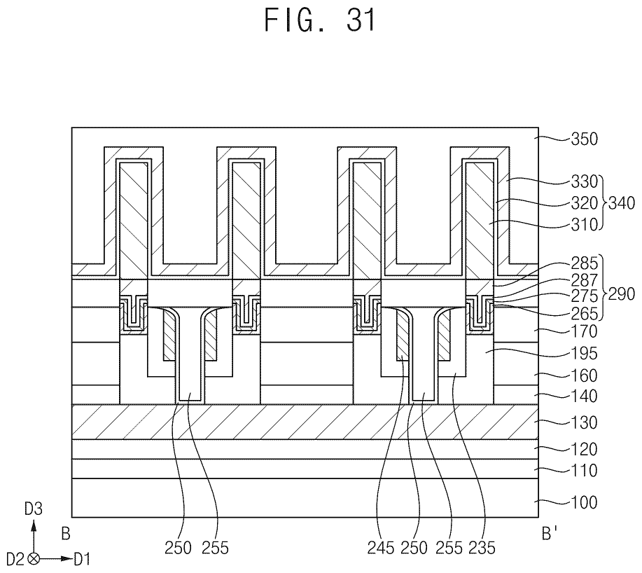

FIGS. 30 and 31 are a plan view and a cross-sectional view, respectively, illustrating a semiconductor device in accordance with example implementations. This semiconductor device may be substantially the same as or similar to the semiconductor device described with reference to FIGS. 1 to 29, except for a shape of the contact structure 290. Thus, the same reference numerals are used for the same elements, and repeated explanations are omitted herein.

Referring to FIGS. 30 and 31, the contact structure 290 may have a pillar shape extending in the third direction D3, and each of opposite sidewalls of the contact structure 290 in the first direction D1 may be perpendicular to an upper surface of the bit line 130.

In example implementations, a sidewall of the contact structure 290 may be aligned in the third direction D3 with a sidewall of the vertical portion of the channel 195 and also be aligned in the third direction D3 with a sidewall of the first capacitor electrode 310. That is, the sidewall of the vertical portion of the channel 195, a sidewall of the first contact pattern 265, a sidewall of an end portion of the second contact pattern 275, a sidewall of an end portion of a barrier pattern 287, a sidewall of the upper portion of the third contact pattern 285, and the sidewall of the first capacitor electrode 310 may be aligned with each other in the third direction D3.

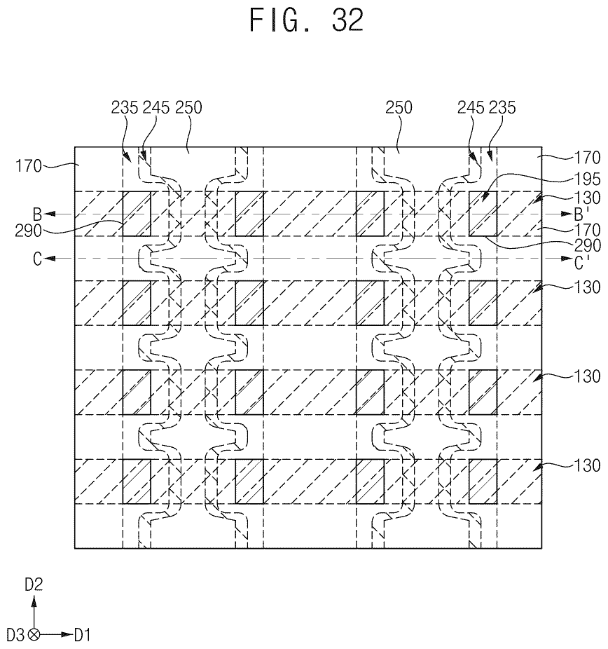

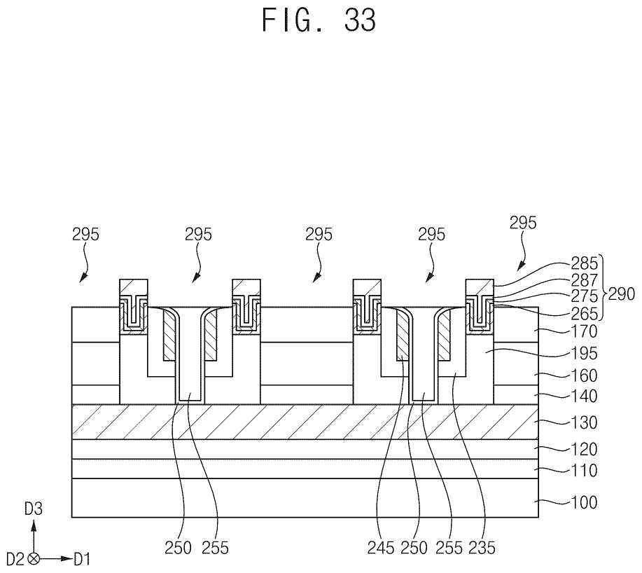

FIGS. 32 and 33 are a plan view and a cross-sectional view, respectively, illustrating a method of manufacturing a semiconductor device in accordance with example implementations.

This method of manufacturing the semiconductor device may include processes substantially the same as or similar to those described with reference to FIGS. 4 to 29 and FIGS. 1 to 3, and thus repeated explanations are omitted herein.

Referring to FIGS. 32 and 33, processes substantially the same as or similar to those described with reference to FIGS. 4 to 26 may be performed, and an etching process may be performed to partially remove the first contact layer 260, the second contact layer 270, the barrier layer 282 and the third contact layer 280, so that the first contact layer 260, the second contact layer 270, the barrier layer 282 and the third contact layer 280 may be transformed into the first contact pattern 265, the second contact pattern 275, the barrier pattern 287 and the third contact pattern 285, respectively. The first to third contact patterns 265, 275, and 285, and the barrier pattern 287 may collectively form the contact structure 290.

In example implementations, the contact structure 290 may be formed in the recess 257 and may have the first width substantially the same as a width of the channel 195, and thus, in a plan view, the contact structure 290 may have an area substantially the same as that of the channel 195.

A plurality of contact structures 290 may be spaced apart from each other in each of the first and second directions D1 and D2, and the fourth opening 295 may be formed between neighboring contact structures 290 to expose the upper surfaces of the third and fourth insulating interlayer patterns 170 and 255, the fourth insulating pattern 250 and the gate insulating pattern 235.

Processes substantially the same as or similar to those illustrated with respect to FIGS. 1 to 3 may be performed, so that the fabrication of the semiconductor device may be completed.

The foregoing is illustrative of example implementations and is not to be construed as limiting thereof. Although a few example implementations have been described, those skilled in the art will readily appreciate that many modifications are possible in the example implementations without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures that perform substantially the same function in substantially the same way to achieve substantially the same result. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a bit line extending in a first direction;
a channel on the bit line, the channel extending in a vertical direction perpendicular to an upper surface of the bit line, and the channel including an oxide semiconductor material;
a gate insulating pattern and a gate electrode sequentially stacked in the first direction from the channel; and
a contact structure including:
a first contact pattern on the channel, the first contact pattern including a reducing material;
a second contact pattern on the first contact pattern, the second contact pattern including a material with a Schottky Barrier Height (SBH) with respect to the channel, wherein the SBH is equal to or less than about 0.2 eV; and
a third contact pattern on the second contact pattern, the third contact pattern including an electrically conductive material.

2. The semiconductor device according to claim 1, wherein the first contact pattern includes titanium, the second contact pattern includes molybdenum, and the third contact pattern includes tungsten.

3. The semiconductor device according to claim 1, comprising a barrier pattern between the second contact pattern and the third contact pattern, wherein the barrier pattern includes a metal nitride.

4. The semiconductor device according to claim 3, wherein each of the first contact pattern, the second contact pattern, the third contact pattern and the barrier pattern is conformally disposed.

5. The semiconductor device according to claim 3, wherein
the third contact pattern includes an upper portion and a lower portion that is disposed under the upper portion and extends in the vertical direction,
the barrier pattern covers a lower surface of the upper portion of the third contact pattern and also covers a sidewall and a lower surface of the lower portion of the third contact pattern,
the second contact pattern covers an outer sidewall and a lower surface of the barrier pattern, and
the first contact pattern covers an outer sidewall and a lower surface of the second contact pattern.

6. The semiconductor device according to claim 1, wherein the channel comprises:
a horizontal portion contacting the upper surface of the bit line; and
a vertical portion contacting an end portion of the horizontal portion and extending in the vertical direction, and
wherein a lower surface of the first contact pattern contacts an upper surface of the vertical portion of the channel.

7. The semiconductor device according to claim 6, wherein a sidewall of the contact structure is aligned in the vertical direction with a sidewall of the vertical portion of the channel.

8. The semiconductor device according to claim 1, comprising a capacitor including a first capacitor electrode, a dielectric layer and a second capacitor electrode sequentially stacked on the contact structure.

9. The semiconductor device according to claim 1, wherein the contact structure includes:
an upper portion having a first width; and
a lower portion having a second width smaller than the first width, and
wherein an upper surface of the channel contacts a lower surface of the lower portion of the contact structure.

10. The semiconductor device according to claim 9, comprising a capacitor including a first capacitor electrode, a dielectric layer and a second capacitor electrode sequentially stacked on the contact structure,
wherein a sidewall of the upper portion of the contact structure is aligned in the vertical direction with a sidewall of the first capacitor electrode, and
wherein a sidewall of the lower portion of the contact structure is aligned in the vertical direction with a sidewall of the channel.

11. The semiconductor device according to claim 6, comprising a division structure contacting a sidewall of the horizontal portion of the channel, a sidewall of the gate insulating pattern and a sidewall of the gate electrode.

12. A semiconductor device comprising:
a bit line extending in a first direction;
a channel on the bit line, the channel extending in a vertical direction perpendicular to an upper surface of the bit line, and the channel including an oxide semiconductor material;
a gate insulating pattern and a gate electrode sequentially stacked in the first direction from the channel; and
a contact structure including:
a first contact pattern on the channel, the first contact pattern including a first metal;
a second contact pattern on the first contact pattern, the second contact pattern including a second metal;
a barrier pattern on the second contact pattern, the barrier pattern including a third metal; and
a third contact pattern on the barrier pattern, the third contact pattern including a fourth metal, and the third contact pattern including:
an upper portion having a first width; and
a lower portion that is disposed under the upper portion and has a second width smaller than the first width.

13. The semiconductor device according to claim 12, wherein
the first contact pattern includes titanium,
the second contact pattern includes molybdenum,
the barrier pattern includes titanium nitride or titanium silicon nitride, and
the third contact pattern includes tungsten.

14. The semiconductor device according to claim 12, wherein
the barrier pattern covers a lower surface of the upper portion of the third contact pattern and also covers a sidewall and a lower surface of the lower portion of the third contact pattern,
the second contact pattern covers a lower surface and a sidewall of the barrier pattern, and
the first contact pattern covers a lower surface and a sidewall of the second contact pattern.

15. The semiconductor device according to claim 12, wherein the lower portion of the third contact pattern overlaps in the first direction with the barrier pattern, the second contact pattern and the first contact pattern.

16. The semiconductor device according to claim 12, a sidewall of an end portion of the first contact pattern, a sidewall of an end portion of the second contact pattern, a sidewall of an end portion of the barrier pattern and a sidewall of an end portion of the third contact pattern are aligned with each other in the vertical direction.

17. A semiconductor device comprising:
a plurality of bit lines on a substrate, each bit line of the plurality of bit lines extending in a first direction parallel to an upper surface of the substrate, and the plurality of bit lines being spaced apart from each other in a second direction that is parallel to the upper surface of the substrate and intersects with the first direction;
a plurality of gate electrodes on the plurality of bit lines, each gate electrode of the plurality of gate electrodes extending in the second direction, and the plurality of gate electrodes being spaced apart from each other in the first direction;
a gate insulating pattern on a sidewall in the first direction of each gate electrode of the plurality of gate electrodes;
a channel contacting an upper surface of each bit line of the plurality of bit lines and a sidewall in the first direction of the gate insulating pattern, the channel including an oxide semiconductor material;
a contact structure including:
a first contact pattern including a reducing material;
a second contact pattern on the first contact pattern, the second contact pattern including a material with a Schottky Barrier Height (SBH) with respect to the channel, wherein the SBH is equal to or less than about 0.2 eV; and
a third contact pattern on the second contact pattern, the third contact pattern including an electrically conductive material; and
a capacitor on the contact structure.

18. The semiconductor device according to claim 17, comprising a barrier pattern between the second contact pattern and the third contact pattern, the barrier pattern including a metal nitride,
wherein the first contact pattern includes titanium,
wherein the second contact pattern includes molybdenum, and
wherein the third contact pattern includes tungsten.

19. The semiconductor device according to claim 17, wherein the first contact pattern includes:
a horizontal portion contacting an upper surface of the channel; and
a vertical portion contacting an end portion in the first direction of the horizontal portion, the vertical portion extending in a vertical direction,
wherein the vertical portion of the first contact pattern contacts a sidewall of the gate insulating pattern, and
wherein an upper surface of the vertical portion of the first contact pattern is higher than an uppermost surface of the gate insulating pattern.

20. The semiconductor device according to claim 19, wherein the capacitor includes a first capacitor electrode, a dielectric layer and a second capacitor electrode sequentially stacked, and
wherein a sidewall of an end portion of the first contact pattern, a sidewall of an end portion of the second contact pattern, a sidewall of an end portion of a barrier pattern, a sidewall of an end portion of the third contact pattern and a sidewall of the first capacitor electrode are aligned with each other in the vertical direction.
